(19) United States
(12) Patent Application Publication
(10) Pub. No.: US 2019/0006550 A1
(43) Pub. Date: Jan. 3, 2019

(54) SEMICONDUCTOR DEVICE

(71) Applicant: Renesas Electronics Corporation, Tokyo (JP)

(72) Inventor: Masahiro FUJII, Tokyo (JP)

(73) Assignee: Renesas Electronics Corporation, Tokyo (JP)

(21) Appl. No.: 15/984,654

(22) Filed: May 21, 2018

(30) Foreign Application Priority Data
Jun. 29, 2017 (JP) 2017-126865

(51) Int. Cl. H01L 31/147; H01L 27/146; H01L 33/50

(52) U.S. Cl. CPC H01L 31/147; H01L 33/50; H01L 27/14625; H01L 27/1469

(57) ABSTRACT

To reduce a size of a semiconductor device. The semiconductor device includes: a first light emitting element which emits first light with a first wavelength to send a first signal; a second light emitting element which emits second light with a second wavelength to send a second signal; a first light receiving element which receives the first light to receive the first signal; and a second light receiving element which overlaps the first light receiving element in plan view and receives the second light transmitted through the first light receiving element to receive the second signal.

### CROSS-REFERENCE TO RELATED APPLICATIONS

The disclosure Japanese Patent Application No. 2017-126865 filed on Jun. 29, 2017 including the specification, drawings and abstract is incorporated herein by reference in its entirety.

### BACKGROUND

The present invention relates to semiconductor devices and more particularly to technology useful for a semiconductor device with a multichannel photocoupler.

Japanese Unexamined Patent Application Publication No. 2008-235599 discloses the structure of a multichannel photocoupler and a method for manufacturing the same. The multichannel photocoupler includes two light emitting elements 14 and two light receiving regions 11, in which one light emitting element 14 is optically coupled to one light receiving element 11 through a transparent first resin 13. In other words, a transparent first resin 13 is provided for each channel and a plurality of transparent first resins 13 are optically separated by an opaque second resin 15.

### SUMMARY

A semiconductor device with a multichannel photocoupler is expected to be compact.

The above and further objects and novel features of the invention will more fully appear from the following detailed description in this specification and the accompanying drawings.

According to one aspect of the present invention, there is provided a semiconductor device which includes: a first light emitting element which emits first light with a first wavelength to send a first signal; a second light emitting element which emits second light with a second wavelength to send a second signal; a first light receiving element which receives the first light to receive the first signal; and a second light receiving element which overlaps the first light receiving element in plan view and receives the second light transmitted through the first light receiving element to receive the second signal.

According to the present invention, a compact semiconductor device is provided.

### BRIEF DESCRIPTION OF THE DRAWINGS

FIG. 1 is a circuit diagram which shows the structure of a semiconductor device according to an embodiment of the invention;

FIG. 2 is a plan view which shows the structure of the semiconductor device according to the embodiment;

FIG. 3 is a sectional view taken along the line X1-X1 of FIG. 2;

FIG. 4 is a plan view of a main part of the semiconductor device according to the embodiment;

FIG. 5 is a sectional view taken along the line X2-X2 of FIG. 4;

FIG. 6 is a schematic diagram which shows the structure of the semiconductor device according to the embodiment;

FIG. 7 is a graph which shows the degree of dependence of light absorption coefficient of silicon and light penetration length on wavelength;

FIG. 8 is a graph which shows the degree of dependence of the sensitivity of a first light receiving element according to the embodiment on wavelength;

FIG. 9 is a graph which shows the degree of dependence of the sensitivity of a second light receiving element according to the embodiment on wavelength;

FIG. 10 is a plan view of a main part of a semiconductor device according to Variation 1;

FIG. 11 is a plan view of a main part of a semiconductor device according to Variation 2; and

FIG. 12 is a plan view of a main part of a semiconductor device according to Variation 3.

### DETAILED DESCRIPTION

The preferred embodiments of the present invention will be described below in different sections or separately as necessary or for the sake of convenience, but the embodiments described as such are not irrelevant to each other unless otherwise stated. One embodiment may be, in whole or in part, a modified, detailed or supplementary form of another. Furthermore, in the preferred embodiments described below, when numerical information for an element (the number of pieces, numerical value, quantity, range, etc.) is given by a specific number, it is not limited to the specific number unless otherwise stated or theoretically limited to the specific number. It may be larger or smaller than the specific number. In the preferred embodiments described below, obviously, constituent elements (including constituent steps) are not necessarily essential unless otherwise stated or considered theoretically essential. Similarly, in the preferred embodiments described below, when a specific form or positional relation is indicated for an element, it should be interpreted to include a form or positional relation which is substantially approximate or similar to the specific form or positional relation unless otherwise stated or theoretically limited to the specific form or positional relation. The same is true for the above numerical information and range.

Next, the preferred embodiments will be described referring to the drawings. In all the drawings that illustrate the preferred embodiments, the members with the same functions are designated by the same reference signs and description thereof is not repeated. In the description of the preferred embodiments, basically the same or similar elements are not repeatedly described unless necessary.

In the drawings used to describe the embodiments, hatching may be omitted even in a sectional view for easy understanding. Also, hatching may be used even in a plan view for easy understanding.

### Embodiment

<Structure of the Semiconductor Device>

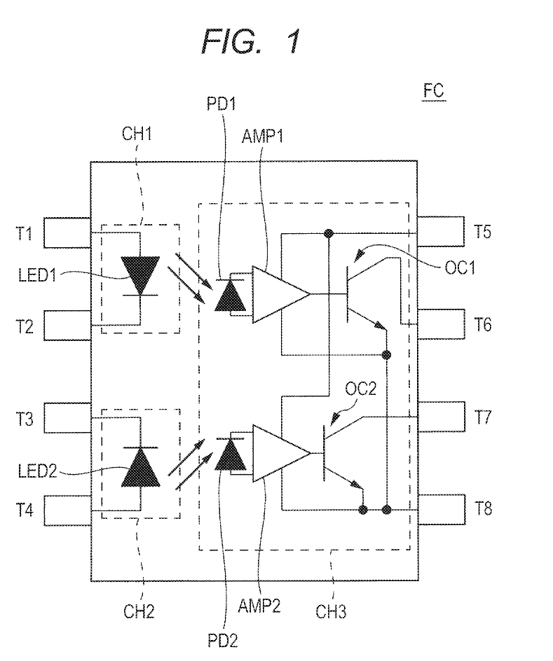

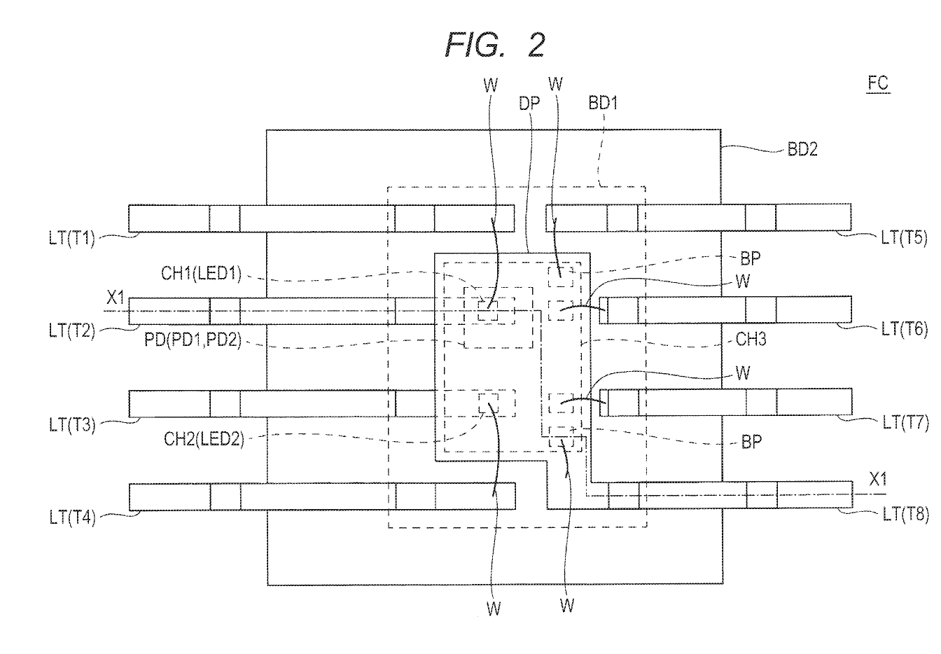

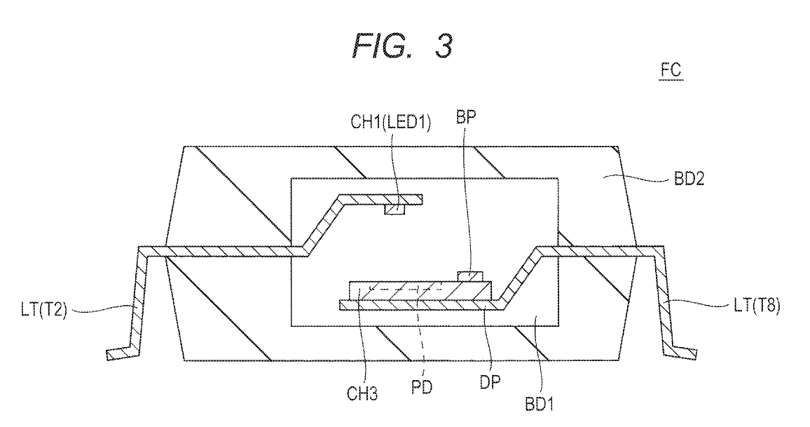

FIG. 1 is a circuit diagram which shows the structure of a semiconductor device according to a first embodiment of the invention. FIG. 2 is a plan view which shows the structure of the semiconductor device according to this embodiment. FIG. 3 is a sectional view taken along the line X1-X1 of FIG. 2.

The semiconductor device according to this embodiment has a multichannel photocoupler. The photocoupler is a device which transfers a signal while keep ng electrical insulation between the primary side (input) and secondary side (output) In other words, the photocoupler is an optical coupling device which converts an electric signal into a light signal and transfers the signal and reconverts a received light signal into an electric signal. Specifically, the photocoupler includes a pair of a light emitting element and a light receiving element The multichannel photocoupler includes two or more pairs of light emitting elements and light receiving elements. This embodiment is described by taking a 2-channel photocoupler as an example.

As shown in FIG. 1, the semiconductor device FC with a photocoupler includes primary (input) terminals T1 to T4 and secondary (output) terminals T5 to T8. The primary terminals T1 and T2 are coupled to a light emitting element LED (Light Emitting Diode) 1 formed in a semiconductor chip CH1 and the primary terminals T3 and T4 are coupled to a light emitting element LED2 formed in a semiconductor chip CH2. The secondary terminals T5 to T8 are coupled to a semiconductor chip CH3 as a light receiving IC, and two light receiving elements PD1 and PD2, two amplifier circuits AMP1 and AMP2, and two output circuits OC1 and OC2 are formed in the semiconductor chip CH3.

In one of the two channels, the light emitting element LED1 is turned on/off according to an input signal (electric signal) entered between the primary terminals T1 and T2 to send a light signal, and the light signal is received by the light receiving element PD1 and converted into an electric signal, then the electric signal is sent as an output signal to the secondary terminals T6 and T8 through the amplifier circuit AMP1 and the output circuit OC1. In the other channel too, similarly, an output signal is sent to the secondary terminals T7 and T8 according to an input signal entered between the primary terminals T3 and T4. The secondary terminal T5 is a terminal for power supply potential (Vdd) and the secondary terminal T8 is a terminal for reference potential (Vss).

As shown in FIG. 2, the semiconductor device FC includes a semiconductor chip CH1 with a light emitting element LED1 formed therein, a semiconductor chip CH2 with a light emitting element LED2 formed therein, and. a semiconductor chip CH3 with light receiving elements PD1 and PD2 formed therein. The semiconductor device EC further includes a plurality of primary leads LT, a plurality of secondary leads LT, a sealing body BD1 made of a material transparent to wavelengths of light from the light emitting elements LED1 and LED2, and a sealing body BD2 made of a material opaque to wavelengths of light from the light emitting elements LED1 and LED2.

The light emitting element LED1 is a light emitting diode which emits light L1 with wavelength λ1. Light L1 is, for example, blue light with wavelength λ1 of 410 nm. The light emitting element LED2 is a light emitting diode which emits light L2 with wavelength λ2. Light L2 is, for example, infrared light with wavelength λ2 of 800 nm.

As will be mentioned later, in this embodiment, it is important that the wavelength λ1 of the light emitting element LED1 should be different from the wavelength λ2 of the light emitting element LED2 and further it is important that the wavelength λ1 of the light emitting element LED1 should be shorter than the wavelength λ2 of the light emitting element LED2.

The semiconductor chip CH1 including the light emitting element LED1 is mounted over the lead LT (T2) and one electrode of the light emitting element LED1 is electrically coupled to the lead LT (T2) and the other electrode is electrically coupled to the lead LT (T1) through a wire W. Similarly, the semiconductor chip CH2 including the light emitting element LED2 is mounted over the lead LT (T3) and one electrode of the light emitting element LED2 is electrically coupled to the lead LT (T3) and the other electrode is electrically coupled to the lead LT (T4) through a wire W.

The semiconductor chip CH3 includes a light receiving element region PD and a plurality of bonding pads (pad electrodes) BP on the main surface of the chip CH3. In the light receiving element region PD, light receiving elements PD1 and PD2 are formed. As will be mentioned later, the light receiving elements PD1 and PD2 are stacked one upon the other. Specifically, the light receiving element PD1 is formed over the light receiving element PD2. Each of the bonding pads BP is coupled to a secondary lead LT through a wire W. Furthermore, two amplifier circuits AMP1 and AMP2 and two output circuits OC1 and OC2 are formed in the semiconductor chip CH3.

The secondary lead LT(8) has a die pad DP at one end and the semiconductor chip CH3 is mounted over the die pad DP. The back surface of the semiconductor chip CH3 is bonded to the die pad DP. In plan view, the die pad DP partially overlaps the primary leads LT(T2) and LT(T3). The die pad DP also overlaps the light emitting elements LED1 and LED2 which are mounted over the primary leads LT(T2) and LT(T3).

As shown in FIG. 2, in plan view, the light emitting element LED1 overlaps the light receiving element region PD and the light emitting element LED2 does not overlap the region PD. In other words, in plan view, the light emitting element LED1 is located inside the light receiving element region PD and the light emitting element LED2 is located outside the light receiving element region PD. The light emitting elements LED1 and LED2 are spaced from each other by the distance equivalent to the distance between the leads LT(T2) and LT(T3), but the light receiving element region PD need not be large enough to overlap both the light emitting elements LED1 and LED2. If the light receiving element region PD is larger, the semiconductor chip CH3 should be larger. Therefore, the light receiving element region PD overlaps only either the light emitting element LED1 or the light emitting element LED2.

When the power of light is the same, the sensitivity of a light receiving element depends on the wavelength of light which it receives. This is because the number of carriers generated in the light receiving element upon reception of light depends on wavelength. Specifically, the sensitivity of the light receiving element to light with a short wavelength is lower than the sensitivity to light with a long wavelength. For this reason, it is important that the light emitting element LED1 for short wavelengths should be preferentially located in a position to overlap the light receiving element region PD.

As shown in FIGS. 2 and 3, the semiconductor chip CH1 including the light emitting element LED1, the semiconductor chip CH2 including the light emitting element LED2, the semiconductor chip CH3 including the light receiving elements PD1 and PD2, one end of each of the primary leads LT, and one end of each of the secondary leads LT are covered by the sealing body BD1. The sealing body BD2 covers the outer surface of the sealing body BD1 in a manner to wrap the sealing body BD1. The other end of each of the primary leads LT and the other end of each of the secondary leads LT protrude from the sealing body BD2.

As shown in FIG. 3, the front surface of the semiconductor chip CH1 faces the front surface of the semiconductor chip CH3. Likewise, the front surface of the semiconductor chip CH2 faces the front surface of the semiconductor chip CH3. In short, the light emitting surfaces of the light emitting elements LED1 and LED2 face the light receiving element region PD.

The sealing body BD1 is made of a resin transparent to wavelengths λ1 and λ2 of the light emitting elements LED1 and LED2. The sealing body PD1 may contain filler (for example, spherical filler of silicon oxide) in order to scatter light L1 and L2 emitted from the light emitting elements LED1 and LED2. The sealing body BD2 is made of a resin opaque to wavelengths λ1 and λ2 of the light emitting elements LED1 and LED2 and has the function to seal the light L1 and L2 emitted from the light emitting elements LED1 and LED2 in the sealing body BD1. The sealing bodies BD1 and BD2 are, for example, made of epoxy resin and contain filler such as titanium oxide, aluminum oxide, mica, aluminum nitride or boron nitride. In order to make it opaque to wavelengths λ1 and λ2, the sealing body B2 contains much filler (for example, spherical filler of silicon oxide). If the sealing body BD1 contains filler, the sealing body BD2 contains more filler than the sealing body BD1.

This means that the light emitting element LED1 and the light receiving element PD1 are optically coupled through the transparent sealing body BD1. Likewise, the light emitting element LED2 and the light receiving element PD2 are optically coupled through the transparent sealing body BD1. In this embodiment, the semiconductor chips CH1, CH2, and CH3 are covered by one sealing body BD1. In other words, the light emitting elements LED1 and LED2 and the light receiving elements PD1 and PD2 are covered by the sealing body BD1. This structure offers a feature that the semiconductor device FC can be compact. In addition, since the light emitting elements LED1 and LED2 and light receiving elements PD1 and PD2 which make up 2 channels are contained in the sealing body BD1, it is important that the wavelength λ1 of the light emitting element LED1 should be different from the wavelength λ2 of the light emitting element LED2.

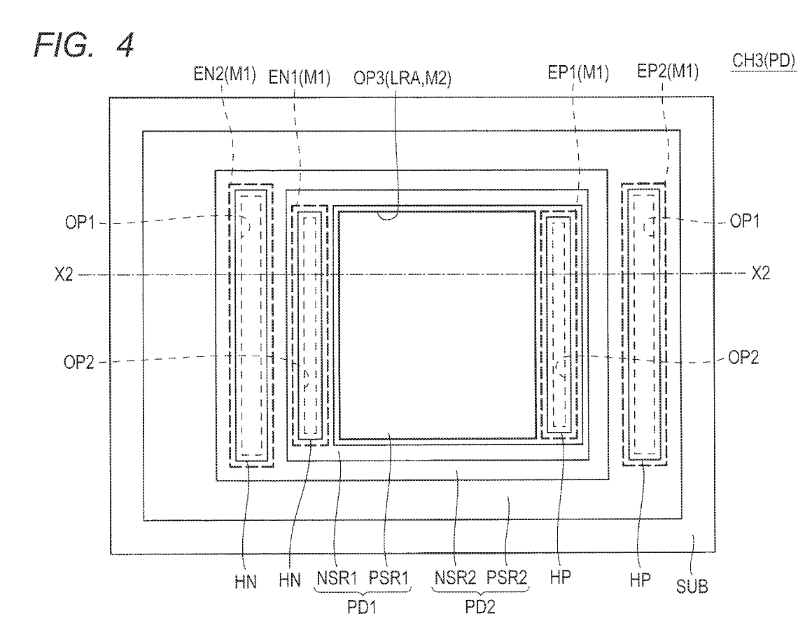

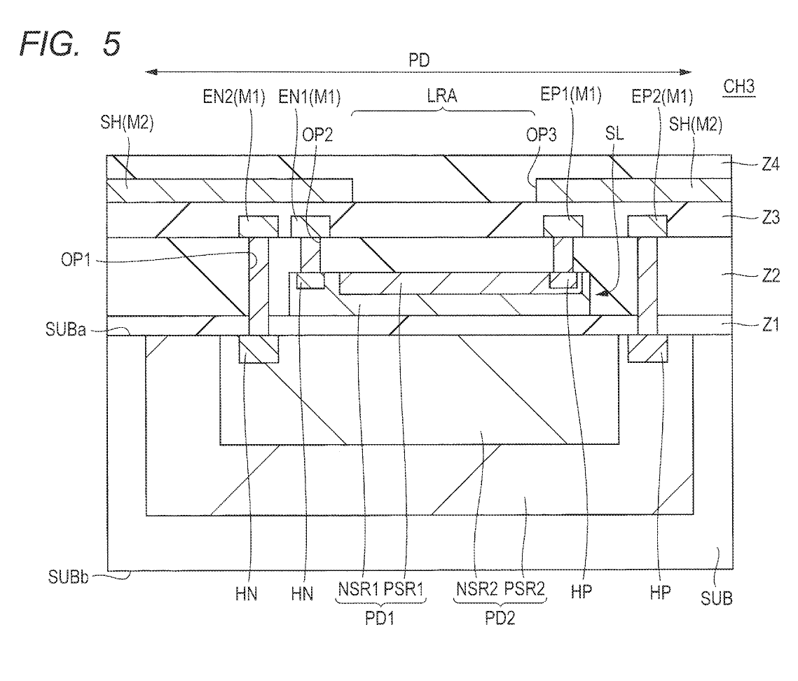

FIG. 4 is a plan view of a main part of the semiconductor device according to this embodiment, more specifically FIG. 4 is a plan view of the light receiving element region PD formed on the semiconductor chip CH3. FIG. 5 is a sectional view taken along the line X2-X2 of FIG. 4.

As shown in FIG. 4, in plan view, the light receiving element PD1 and light receiving element PD2 overlap each other and as shown in FIG. 5, the light receiving element PD1 is formed above the light receiving element PD2. Since the light receiving elements PD1 and PD2 overlap each other in this way, the area of the light receiving element region PD can be decreased and the plane area of the semiconductor chip CH3 can be decreased.

As shown in FIG. 5, the light receiving element PD2 is formed in the semiconductor substrate SUB. The semiconductor substrate SUB is, for example, made of p-type monocrystalline silicon and has a front surface SUBa and a back surface SUBb which are opposite to each other.

As shown in FIG. 5, the light receiving element PD2 includes a p-type semiconductor region PSR2 formed in the semiconductor substrate SUB and an n-type semiconductor region NSR2 formed in the p-type semiconductor region PSR2, in which these regions make a PN junction. In other words, the p-type semiconductor region PSR2 is deeper than the n-type semiconductor region NSR2 and the n-type semiconductor region NSR2 is surrounded by the p-type semiconductor region PSR2. The impurity concentration of the p-type semiconductor region PSR2 is, for example, 1×10¹⁶ cm⁻³ or more and the impurity concentration of the n-type semiconductor region NSR2 is 1×10¹⁵ cm⁻³. The depth of the n-type semiconductor region NSR2 is, for example, about 10 μm. With the above relation in terms of impurity concentration, when a reverse bias is applied to the PN junction of the light receiving element PD2, a depletion layer spreads almost inside the n-type semiconductor region NSR2 Since the incident light on the light receiving element PD2 generates carriers in the above depletion layer, the carrier generation efficiency with respect to incident light can be improved by increasing the thickness of the depletion layer. Specifically, when the depth of the n-type semiconductor region NSR2 is about as large as 10 μm, the carrier generation efficiency with respect to incident light (namely, efficiency of conversion into electric signal) can be improved.

Furthermore, as shown in FIG. 5, a p-type semiconductor region (high concentration p-type semiconductor region) HP with a higher impurity concentration than the p-type semiconductor region PSR2 is formed in the p-type semiconductor region PSR2 and an electrode (p-side electrode) EP2 is coupled to the p-type semiconductor region HP. Also, an n-type semiconductor region (high concentration n-type semiconductor region) HN with a higher impurity concentration than the n-type semiconductor region NSR2 is formed in the n-type semiconductor region NSR2 and an electrode (n-side electrode) EN2 is coupled to the n-type semiconductor region HN.

As shown in FIG. 4, in plan view, the p-type semiconductor region PSR2 and the n-type semiconductor region NSR2 are each rectangular (rectangle) and the p-type semiconductor region PSR2 is larger than the n-type semiconductor region NSR2. The n-type semiconductor region NSR2 is located inside the p-type semiconductor region PSR2 and the n-type semiconductor region NSR2 is surrounded by the p-type semiconductor region PSR2.

As shown in FIG. 5, a semiconductor layer SL is formed over the front surface SUBa of the semiconductor substrate SUB through an insulating film Z1. The insulating film Z1 is, for example, a silicon oxide film. The semiconductor layer SL made of polycrystalline silicon. An n-type semiconductor region NSR1 is formed in the semiconductor layer SL and a p-type semiconductor region PSR1 is formed in the n-type semiconductor region NSR1. The light receiving element PD1 has the n-type semiconductor region NSR1 and p-type semiconductor region PSR1 which are formed in the semiconductor layer SL, in which these regions make a PN junction. The thickness of the semiconductor layer SL is about 0.2 μm, the depth of the n-type semiconductor region NSR1 is about 0.2 μm and the depth of the p-type semiconductor region PSR1 is about 0.1 μm. Since the semiconductor layer SL must transmit light L2 from the light emitting element LED2, it is relatively thin. The n-type semiconductor region NSR1 and the p-type semiconductor region PSR1 each have an impurity concentration of 1×10^{16˜18} cm⁻³.

As shown in FIG. 5, an n-type semiconductor region with a higher impurity concentration than the n-type semiconductor region NSR1 (high concentration n-type semiconductor region) HN is formed in the n-type semiconductor region NSR1 and an electrode (n-side electrode) EN1 is coupled to the n-type semiconductor region HN. Also, a p-type semiconductor region with a higher impurity concentration than the p-type semiconductor region PSR1 (high concentration p-type semiconductor region) is formed in the p-type semiconductor region PSR1 and an electrode (p-side electrode) EP1 is coupled to the p-type semiconductor region HP.

Furthermore, as shown in FIG. 4, the n-type semiconductor region NSR1 and the p-type semiconductor region PSR1 are each rectangular (rectangle) and the n-type semiconductor region NSR1 is larger than the p-type semiconductor region PSR1. The p-type semiconductor region PSR1 is located inside the n-type semiconductor region NSR1 and the p-type semiconductor region PSR1 is surrounded by the n-type semiconductor region NSR1. The n-type semiconductor region NSR1 is located inside the n-type semiconductor region NSR2 which configures the light receiving element PD2 and the n-type semiconductor region NSR1 is surrounded by the n-type semiconductor region NSR2.

Furthermore, as shown in FIG. 5, an insulating film Z2 is formed over the semiconductor substrate SUB in a manner to cover the insulating film Z1 and the semiconductor layer SL and the electrodes EP1, EP2, EN1, and EN2 are formed over the insulating film Z2. The electrodes EP1, EP2, EN1, and EN2 are formed in a first wiring layer M1. The first wiring layer M1 lies not only over the insulating film Z2 but also inside openings OP1 made in the insulating films Z1 and Z2 and openings OP2 made in the insulating film Z2. In other words, the electrode EP1 includes a wiring portion formed over the insulating film Z2 and a coupling portion formed in the opening OP2 and the coupling portion is coupled to the p-type semiconductor region HP formed in the p-type semiconductor region PSR1. Likewise, the electrode EN1 includes a wiring portion formed over the insulating film Z2 and a coupling portion formed in the opening OP2 and the coupling portion is coupled to the n-type semiconductor region. HN formed in the n-type semiconductor region NSR1. Also, the electrode EP2 includes a wiring portion formed over the insulating films Z1 and Z2 and a coupling portion formed in the opening OP1 and the coupling portion is coupled to the p-type semiconductor region HP formed in the p-type semiconductor region PSR2. Likewise, the electrode EN2 includes a wiring portion formed over the insulating films Z1 and Z2 and a coupling portion formed in the opening OP1 and the coupling portion is coupled to the n-type semiconductor region HN formed in the n-type semiconductor region NSR2.

The first wiring layer M1 is a laminated film which includes a barrier film of titanium nitride (TiN), titanium tungsten (TiW) or the like and an aluminum (Al)-based main metal film formed over the barrier film. In each of the above electrodes, the wiring portion may be formed from the laminated film and the coupling portion may be a plug electrode made of tungsten.

Furthermore, as shown in FIG. 5, an insulating film Z3 is formed over the insulating film Z2 in a manner to cover the electrodes EP1, EN1, EP2, and EN2. A light shielding film SH is formed over the insulating film Z3. The light shielding film SH includes a second wiring layer M2 which has the same film structure as the first wiring layer M1. The light shielding film SH covers part of the semiconductor layer SL and the electrodes EP1, EN1, EP2, and EN2 and has an opening OP3 which exposes a light receiving area LRA for the light receiving elements PD1 and PD2. The light receiving area LRA is an area to take light L1 from the light emitting element LED1 and light L2 from the light emitting element LED2 into the light receiving elements PD1 and PD2.

As shown in FIGS. 4 and 5, in the light receiving area LRA (namely, opening OP3), the p-type semiconductor region PSR1 and n-type semiconductor region NSR1 which configure the light receiving element PD1, and the n-type semiconductor region NSR2 and p-type semiconductor region PSR2 which configure the light receiving element PD2 are exposed from the light shielding film SR. The expression “exposed” here means that the p-type semiconductor region PSR1 and n-type semiconductor region NSR1 which configure the light receiving element PD1, and the n-type semiconductor region NSR2 and p-type semiconductor region PSR2 which configure the light receiving element PD2 have an area which overlaps the light receiving area LRA (namely, opening OP3). In FIG. 4, the opening OP3 of the light shielding film SH (namely, light receiving area LRA) is shown. In other words, the light shielding film SH, which exists around the opening OP3 though not shown in FIG. 4, covers, for example, the electrodes EP1, EP2, EN1, and EN2.

Furthermore, as shown in FIG. 5, an insulating film Z4 is formed over the insulating film Z3 in a manner to cover the light shielding film SH. The insulating films Z2 to Z4 are, for example, silicon oxide films.

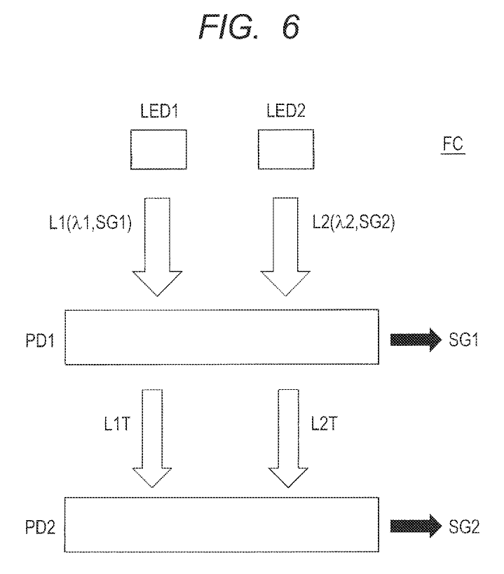

FIG. 6 is a schematic diagram which shows the structure of the semiconductor device according to this embodiment. As shown in FIG. 6, light L1 emitted from the light emitting element LED1 and light L2 emitted from the light emitting element LED2 enter the light receiving element PD1, and light L1 transmitted through the light receiving element PD1 (referred to as transmitted light L1T) and light L2 transmitted through the light receiving element PD1 (referred to as transmitted light L2T) enters the light receiving element PD2.

The light emitting element LED1 emits light L1 with wavelength λ1 and sends a signal SG1. Then, the light receiving element PD1 receives the light L1 and signal SG1. The light emitting element LED2 emits light L2 with wavelength λ2 and sends a signal SG2. Then, the light receiving element PD2 receives transmitted light L2T and signal SG2. Here, wavelength λ1 and wavelength λ2 are different from each other. Since light L1 and light L2 are emitted simultaneously, when the light receiving element PD1 receives light L1, light L2 becomes noise. Also, when the light receiving element PD2 receives transmitted light L2T, transmitted light L1t becomes noise. Therefore, in order to ensure that the light receiving element PD1 receives the signal SG1 of light L1 with high accuracy and the light receiving element PD2 receives the signal SG2 of light L2 with high accuracy, it is imperative that light L1 should meet the conditions for the light receiving element PD1 to provide low transmissivity and light L2 should meet the conditions for the light receiving element PD2 to provide high transmissivity.

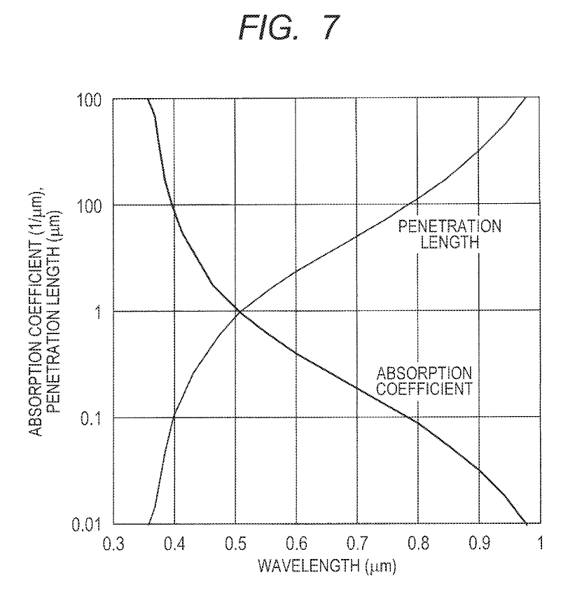

FIG. 7 is a graph which shows the degree of dependence of light absorption coefficient of silicon and light penetration length on wavelength. The graph reveals that when the wavelength is shorter, the absorption coefficient is higher (in other words, penetration length is shorter) and when the wavelength is longer, the absorption coefficient is lower (in other words, penetration length is longer). In other words, it has been demonstrated that it is effective to use short wavelength light as light L1 received by the light receiving element PD1 and long wavelength light as light L2 received by the light receiving element PD2. In short, it is important that the wavelength λ1 of light L1 should be shorter than the wavelength λ2 of light L2. Also, it is important that the light receiving element PD1 should have a thickness to absorb most of light L1 and transmit most of light L2 and the light receiving element PD2 should have a thickness to absorb a sufficient amount of light L2. In short, it is important to satisfy the following relation: thickness of the light absorption region (semiconductor layer SL) of the light receiving element PD1<thickness of the light absorption region (n-type semiconductor region NSR2) of the light receiving element PD2.

In order to enable the light receiving element PD1 to receive the signal SG1 of light L1 with high accuracy without being affected by the noise mentioned above, it is important that the following relation should be satisfied:

S11≥2×S12 (Formula 1)

where
S11: sensitivity of the light receiving element PD1 with respect to wavelength λ1, and
S12: sensitivity of the light receiving element PD1 with respect to wavelength λ2.

In order to enable the light receiving element PD2 to receive the signal SG2 of light L2 with high accuracy, it is important that the following relation should be satisfied:

S22×TM2≥2×S21×TM1 (Formula 2)

where
S21: sensitivity of the light receiving element PD2 with respect to wavelength λ1,
S22: sensitivity of the light receiving element PD2 with respect to wavelength λ2,
TM1: transmissivity of light L1 of the light receiving element PD1, and
TM2: transmissivity of light L2 of the light receiving element PD1.

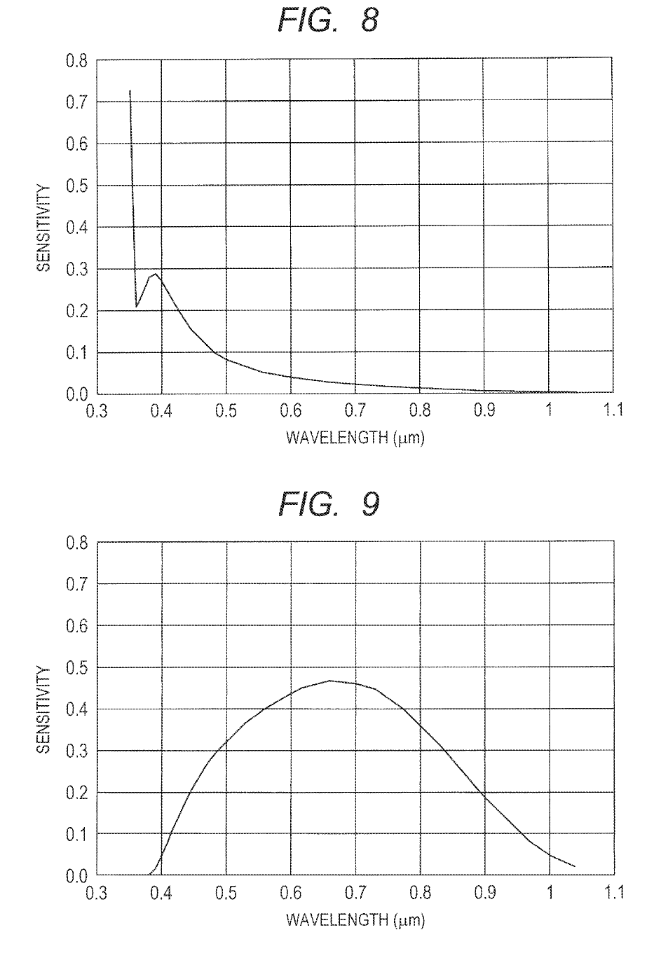

FIG. 8 is a graph which shows the degree of dependence of the sensitivity of the light receiving element (first light receiving element) PD1 according to this embodiment on wavelength. FIG. 9 is a graph which shows the degree of dependence of the sensitivity of the light receiving element (second light receiving element) PD2 according to this embodiment on wavelength. FIGS. 8 and 9 show the result of simulation under the conditions of this embodiment.

As shown in FIG. 8, the sensitivity ratio for the light receiving element PD1 is as follows:

S11:S12=24:1 (Formula 3)

As shown in FIG. 9, the sensitivity ratio for the light receiving element PD2 is as follows:

S22×TM2:S12×TM1=3.9:1 (Formula 4)

Thus, the above Formula 1 and Formula 2 are satisfied.

Therefore, according to this embodiment, the light receiving element PD1 and the light receiving element PD2 can receive the signal SG1 from the light emitting element LED1 and the signal SG2 from the light emitting element LED2 with high accuracy, respectively.

<Features of This Embodiment>

Since the laminated structure is adopted for the light receiving elements PD1 and PD2, the semiconductor chip CH3 which includes the light receiving elements PD1 and PD2 can be compact.

Since the light receiving elements PD1 and PD2 are stacked one upon the other and the wavelength λ1 of light L1 received by the light receiving element PD1, located nearer to the light emitting elements LED1 and LED2, is relatively short and the wavelength λ2 of light L2 received by the light receiving element PD2 is relatively long, the light receiving elements PD1 and PD2 can receive signals with high accuracy.

Since the light emitting element LED1 and light receiving element PD1 which configure one channel and the light emitting element LED2 and light receiving element PD2 which configure one channel are covered by one sealing body BD1, the semiconductor device with a 2-channel photocoupler can be compact.

<Variation 1>

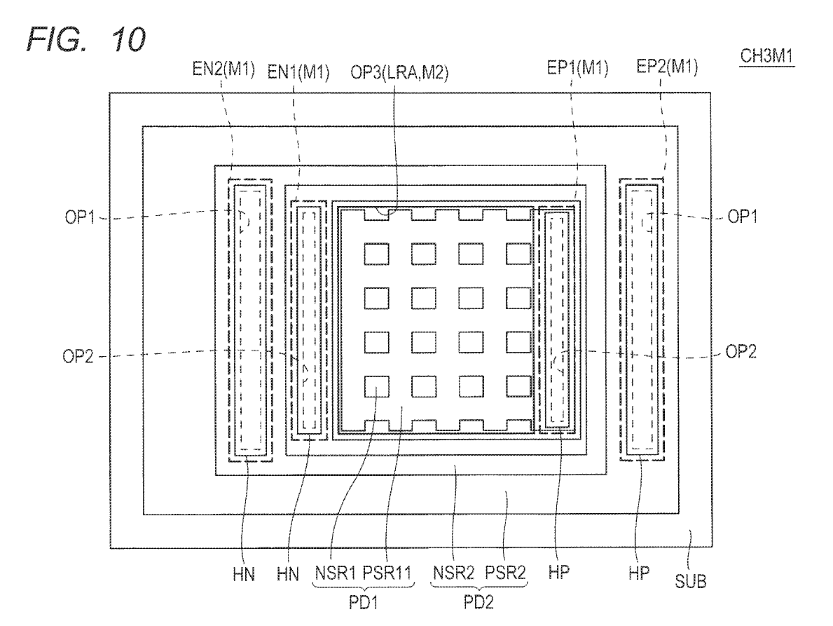

FIG. 10 is a plan view of a main part of a semiconductor device according to Variation 1. In Variation 1, the p-type semiconductor region PSR1 according to the above embodiment as shown in FIG. 4 is modified. In the semiconductor chip CH3M1 according to Variation 1, the p-type semiconductor region PSR11 is grid-like (grid pattern) in plan view. The other constituent elements are the same as in the above embodiment. This improves the area of the PN junction made by the p-type semiconductor region PSR11 and n-type semiconductor region NSR1 and thus improves the sensitivity of the light receiving element PD1.

<Variation 2>

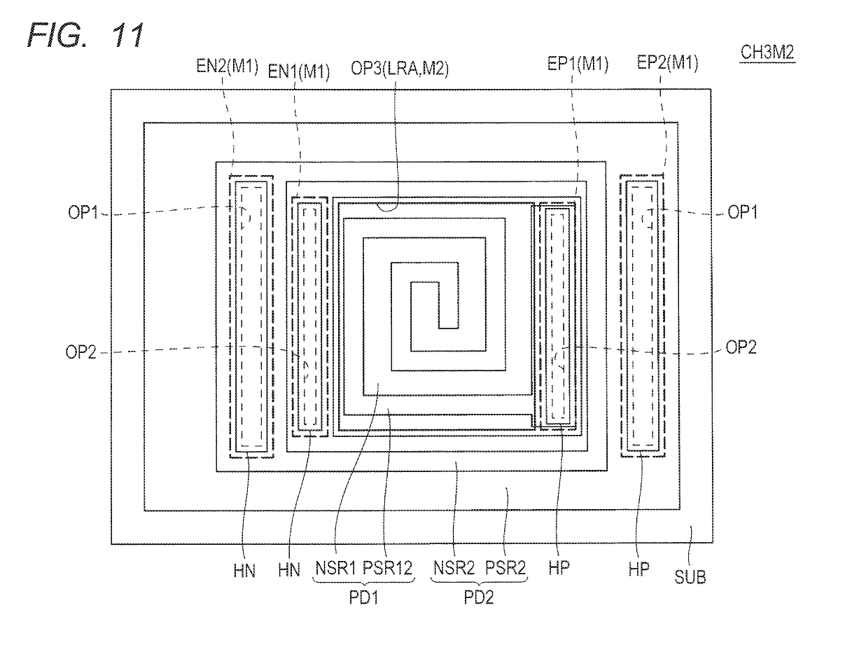

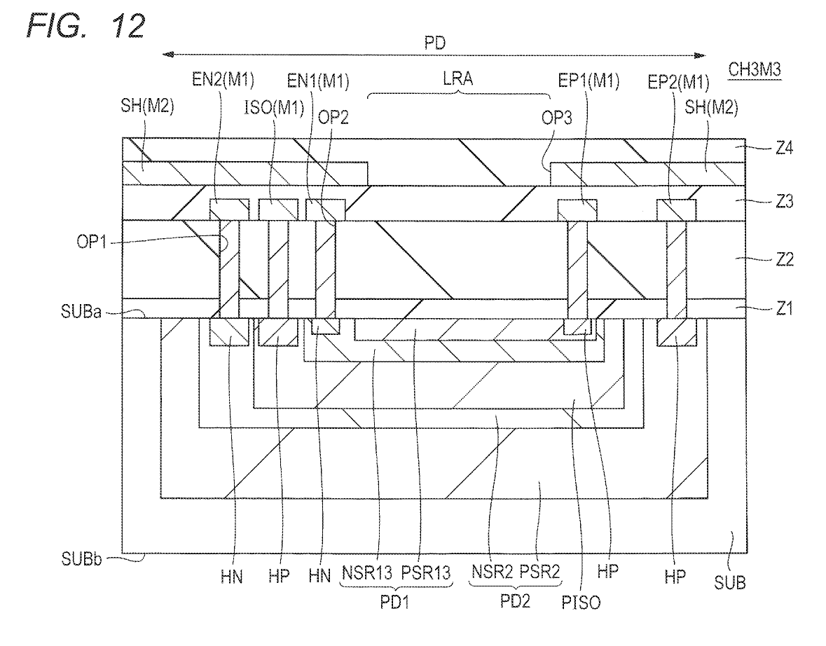

FIG. 11 is a plan view of a main part of a semiconductor device according to Variation 2. In Variation 2, the p-type semiconductor region PSR1 according to the above embodiment as shown in FIG. 4 is modified. In the semiconductor chip CH3M2 according to Variation 2, the p-type semiconductor region PSR12 is spiral (spiral pattern) in plan view. The other constituent elements are the same as in the above embodiment. This improves the area of the PN junction made by the p-type semiconductor region PSR12 and n-type semiconductor region NSR1 as compared with the above embodiment and thus improves the sensitivity of the light receiving element PD1.

<Variation 3>

FIG. 12 is a sectional view of a main part of a semiconductor device according to Variation 3. In the semiconductor chip CH3M3 according to Variation 3, the light receiving element PD1 is also formed in the semiconductor substrate SUB like the light receiving element PD2.

As shown in FIG. 12, the light receiving element PD1 includes an n-type semiconductor region NSR13 formed in the semiconductor substrate SUB and a p-type semiconductor region PSR13 formed in the n-type semiconductor region NSR13, in which both the regions make a PN junction. As in the above embodiment, the light receiving element PD2 includes a p-type semiconductor region PSR2 formed in the semiconductor substrate SUB and an n-type semiconductor region NSR2 formed in the p-type semiconductor region PSR2, in which both the regions make a PN junction. The n-type semiconductor region NSR13 of the light receiving element PD1 is formed in the n-type semiconductor region NSR2 of the light receiving element PD2 through a p-type semiconductor region PISO. In other words, the p-type semiconductor region PISO is formed in the n-type semiconductor region NSR2 and the n-type semiconductor region NSR13 is formed in the p-type semiconductor region PISO.

The p-type semiconductor region PISO is a semiconductor region to isolate the light receiving element PDA from the light receiving element PD2 electrically. An isolation electrode ISO is coupled to the p-type semiconductor region PISO and a lower voltage is applied to the isolation electrode ISO than to the electrodes EN1 and EN2.

For the p-type semiconductor region PSR13, the impurity concentration is 3×10¹⁹ cm⁻³ and the depth is 0.1 μm; for the n-type semiconductor region NSR13, the impurity concentration is 2×10¹⁸ cm⁻³ and the depth is 0.2 μm; and for the p-type semiconductor region PISO, the impurity concentration is 2×10¹⁷ cm⁻³ and the depth is 0.8 μm. As in the above embodiment, for the n-type semiconductor region NSR2, the impurity concentration is 1×10¹⁵ cm⁻³ and the depth is 10 μm; and for the p-type semiconductor region PSR2, the impurity concentration is, for example, 1×10¹⁶ cm⁻³.

The invention made by the present inventors has been so far explained concretely in reference to the preferred embodiments thereof. However, the invention is not limited to the above embodiments and it is obvious that these details may be modified in various ways without departing from the gist thereof.

What is claimed is:

1. A semiconductor device comprising:
a first light emitting element emitting first light with a first wavelength to send a first signal;
a second light emitting element emitting second light with a second wavelength different from the first wavelength to send a second signal;
a first light receiving element receiving the first light to receive the first signal; and
a second light receiving element overlapping the first light receiving element in plan view and receiving the second light transmitted through the first light receiving element to receive the second signal.

2. The semiconductor device according to claim 1, wherein the first wavelength is shorter than the second wavelength.

3. The semiconductor device according to claim 1,
wherein the second light receiving element includes a first semiconductor region of a first conductivity type and a second semiconductor region which is formed in the first semiconductor region and is of a second conductivity type as a conductivity type opposite to the first conductivity type, and
wherein the first light receiving element includes a third semiconductor region of the second conductivity type and a fourth semiconductor region which is formed in the third semiconductor region and is of the first conductivity type.

4. The semiconductor device according to claim 3, wherein the third semiconductor region is rectangular in plan view.

5. The semiconductor device according to claim 3, wherein the third semiconductor region is grid-like in plan view.

6. The semiconductor device according to claim 3, wherein the third semiconductor region is spiral in plan view.

7. The semiconductor device according to claim 3,
wherein the first semiconductor region and the second semiconductor region which configure the second light receiving element are formed in a semiconductor substrate, and
wherein the third semiconductor region and the fourth semiconductor region which configure the first light receiving element are formed in a semiconductor layer formed over the semiconductor substrate.

8. The semiconductor device according to claim 1,
wherein the first light emitting element is formed in a first semiconductor chip,
wherein the second light emitting element is formed in a second semiconductor chip,
wherein the first light receiving element and the second light receiving element are formed in a third semiconductor chip,
the semiconductor device further comprising:
a first sealing body located between to first semiconductor chip and the third semiconductor chip and between the second semiconductor chip and the third semiconductor chip; and
a second sealing body covering the first semiconductor chip, the second semiconductor chip, the third semiconductor chip, and the first sealing body.

9. A semiconductor device comprising:
a first semiconductor chip in which a first light emitting element emitting first light with a first wavelength to send a first signal is formed;
a second semiconductor chip in which a second light emitting element emitting second light with a second wavelength different from the first wavelength to send a second signal is formed; and
a third semiconductor chip in which a first light receiving element receiving the first light to receive the first signal and a second light receiving element receiving the second light transmitted through the first light receiving element to receive the second signal are formed,
the third semiconductor chip comprising:
a semiconductor substrate;
a first semiconductor region of a first conductivity type which is formed in the semiconductor substrate;
a second semiconductor region which is formed in the first semiconductor region and is of a second conductivity type as a conductivity type opposite to the first conductivity type;
a semiconductor layer formed over a main surface of the semiconductor substrate through a first insulating film;
a third semiconductor region which is formed in the semiconductor layer and is of the second conductivity type;
a fourth semiconductor region which is formed in the third semiconductor region and is of the first conductivity type;
a second insulating film covering the semiconductor layer; and
a light shielding film which is formed over the second insulating film, covers part of the semiconductor layer in plan view and has an opening partially exposing the first semiconductor region, the second semiconductor region, the third semiconductor region, and the fourth semiconductor region,
wherein the second light receiving element includes the first semiconductor region and the second semiconductor region, and
wherein the first light receiving element includes the third semiconductor region and the fourth semiconductor region.

10. The semiconductor device according to claim 9, wherein the opening made in the light shielding film corresponds to a light receiving area to make the first light and the second light enter the first light receiving element and the second light receiving element.

11. The semiconductor device according to claim 9, further comprising:
a first electrode coupled to the third semiconductor region and formed over the second insulating film; and
a second electrode coupled to the fourth semiconductor region and formed over the second insulating film,
wherein the first electrode and the second electrode are covered by the light shielding film in plan view.

12. The semiconductor device according to claim 9, wherein the first wavelength is shorter than the second wavelength.

13. A semiconductor device comprising:
a first semiconductor chip in which a first light emitting element emitting first light with a first wavelength to send a first signal is formed;
a second semiconductor chip in which a second light emitting element emitting second light with a second wavelength different from the first wavelength to send a second signal is formed; and
a third semiconductor chip in which a first light receiving element receiving the first light to receive the first signal and a second light receiving element receiving the second light transmitted through the first light receiving element to receive the second signal are formed,
the third semiconductor chip comprising:
a semiconductor substrate;
a first semiconductor region of a first conductivity type which is formed in the semiconductor substrate;
a second semiconductor region which is formed in the first semiconductor region and is of a second conductivity type as a conductivity type opposite to the first conductivity type;
a third semiconductor region which is formed in the second semiconductor region and is of the first conductivity type;
a fourth semiconductor region which is formed in the third semiconductor region and is of the second conductivity type; and
a fifth semiconductor region which is formed in the fourth semiconductor region and is of the first conductivity type, wherein the second light receiving element includes the first semiconductor region and the second semiconductor region, and
wherein the first light receiving element includes the fourth semiconductor region and the fifth semiconductor region.
